(19) United States
(12) Patent Application Publication
(10) Pub. No.: US 2025/0336746 A1
(43) Pub. Date: Oct. 30, 2025

(54) SEMICONDUCTOR DEVICES AND METHODS OF MANUFACTURING SEMICONDUCTOR DEVICES

(71) Applicant: Amkor Technology Singapore Holding Pte. Ltd.

(72) Inventors: Kyun Ahn, Gyeonggi-do (KR); Wang Gu Lee, Seoul (KR); In Su Mok, Incheon (KR); Hee Jun Jang, Chungcheongbuk-do (KR); Won Chul Do, Seoul (KR)

(73) Assignee: Amkor Technology Singapore Holding Pte. Ltd., (omitted)

(21) Appl. No.: 18/957,321

(22) Filed: Nov. 22, 2024

Related U.S. Application Data
(60) Provisional application No. 63/638,834, filed on Apr. 25, 2024.

(51) Int. Cl. H01L 23/31; H01L 23/48; H01L 23/528

(52) U.S. Cl. CPC H01L 23/3171; H01L 23/3192; H01L 23/481; H01L 23/528

(57) ABSTRACT

An example method of manufacturing an electronic device can include providing a device wafer including an active region comprising a front-end-of-line (FEOL) region opposite a back-end-of-line (BEOL) region. The FEOL region can include buried power rails, and the BEOL region can include a dielectric structure having a side exposed from the BEOL region. A support substrate having a substrate dielectric can be coupled to the dielectric structure. A bond interface is disposed between the substrate dielectric and the dielectric structure. A passivation structure can be provided over the FEOL region. Conductive vias can be provided through the passivation structure. The conductive vias can include a conductor coupled to the buried power rails. A substrate can be coupled to the passivation structure. The substrate can include a power network electrically coupled to the conductive vias.

### CROSS-REFERENCE TO RELATED APPLICATIONS

This application claims priority to U.S. Provisional Patent Application No. 63/638,834 filed on Apr. 25, 2024 and entitled “SEMICONDUCTOR DEVICES AND METHODS OF MANUFACTURING SEMICONDUCTOR DEVICES,” which is incorporated herein by reference.

### TECHNICAL FIELD

The present disclosure relates, in general, to electronic devices, and more particularly, to semiconductor devices and methods for manufacturing semiconductor devices.

### BACKGROUND

Prior semiconductor packages and methods for forming semiconductor packages are inadequate, resulting in, for example, excess cost, decreased reliability, relatively low performance, or package sizes that are too large. Further limitations and disadvantages of conventional and traditional approaches will become apparent to one of skill in the art, through comparison of such approaches with the present disclosure and reference to the drawings.

### BRIEF DESCRIPTION OF THE DRAWINGS

FIG. 1 shows a cross-sectional view of an example electronic device.

FIGS. 2A to 2H show cross-sectional views of an example method for manufacturing an example electronic device.

The following discussion provides various examples of semiconductor devices and methods of manufacturing semiconductor devices. Such examples are non-limiting, and the scope of the appended claims should not be limited to the particular examples disclosed. In the following discussion, the terms “example” and “e.g.” are non-limiting.

The figures illustrate the general manner of construction, and descriptions and details of well-known features and techniques may be omitted to avoid unnecessarily obscuring the present disclosure. In addition, elements in the drawing figures are not necessarily drawn to scale. For example, the dimensions of some of the elements in the figures may be exaggerated relative to other elements to help improve understanding of the examples discussed in the present disclosure. The same reference numerals in different figures denote the same elements.

The term “or” may mean any one or more of the items in the list joined by “or”. As an example, “x or y” may mean any element of the three-element set {(x), (y), (x, y)}. As another example, “x, y, or z” means any element of the seven-element set {(x), (y), (z), (x, y), (x, z), (y, z), (x, y, z)}.

The terms “comprises,” “comprising,” “includes,” and “including” are “open ended” terms and specify the presence of stated features, but do not preclude the presence or addition of one or more other features.

The terms “first,” “second,” etc. may be used herein to describe various elements. The elements described using “first,” “second,” etc. should not be limited by the terms “first,” “second,” etc. These terms are only used to distinguish one element from another. Thus, for example, a first element discussed in the present disclosure could be termed a second element without departing from the teachings of the present disclosure.

Unless specified otherwise, the term “coupled” may be used to describe two elements directly contacting each other or to describe two elements indirectly coupled by one or more other elements. For example, if element A is coupled to element B, then element A can be directly contacting element B or indirectly coupled to element B by an intervening element C. Similarly, the terms “over” or “on” may be used to describe two elements directly contacting each other or to describe two elements indirectly coupled by one or more other elements. As used herein, the term “coupled’ can refer to an electrical coupling or a mechanical coupling.

### DESCRIPTION

An example method of manufacturing an electronic device can include providing a device wafer including an active region comprising a front-end-of-line (FEOL) region opposite a back-end-of-line (BEOL) region. The FEOL region can include buried power rails, and the BEOL region can include a dielectric structure having a side exposed from the BEOL region. A support substrate having a substrate dielectric can be coupled to the dielectric structure. A bond interface is disposed between the substrate dielectric and the dielectric structure. A passivation structure can be provided over the FEOL region. Conductive vias can be provided through the passivation structure. The conductive vias can include a conductor coupled to the buried power rails. A substrate can be coupled to the passivation structure. The substrate can include a power network electrically coupled to the conductive vias.

An example electronic device can include a device wafer including an active region comprising a front-end-of-line (FEOL) region opposite a back-end-of-line (BEOL) region. The FEOL region can include buried power rails. The BEOL region can include a dielectric structure having a side exposed from the BEOL region. A support substrate having a substrate dielectric can be coupled to the dielectric structure. A bond interface can be disposed between the substrate dielectric and the dielectric structure. A passivation structure disposed over the FEOL region. Conductive vias can extend through the passivation structure and can comprise a conductor coupled to the buried power rails. A substrate can be coupled to the passivation structure. The substrate can comprise a power network electrically coupled to the conductive vias.

Another example electronic device can include a device wafer including buried power rails in an active region. The active region can include a dielectric structure on a first side. A support substrate coupled to the dielectric structure with a bond interface disposed between the support substrate and the dielectric structure. A passivation structure can be coupled to a second side of the active region opposite the first side. Conductive vias can extend extending through the passivation structure. The conductive vias can be coupled to the buried power rails. A substrate can be coupled to the passivation structure. The substrate comprising a power network electrically coupled to the conductive vias.

Other examples are included in the present disclosure. Such examples may be found in the figures, in the claims, or in the description of the present disclosure.

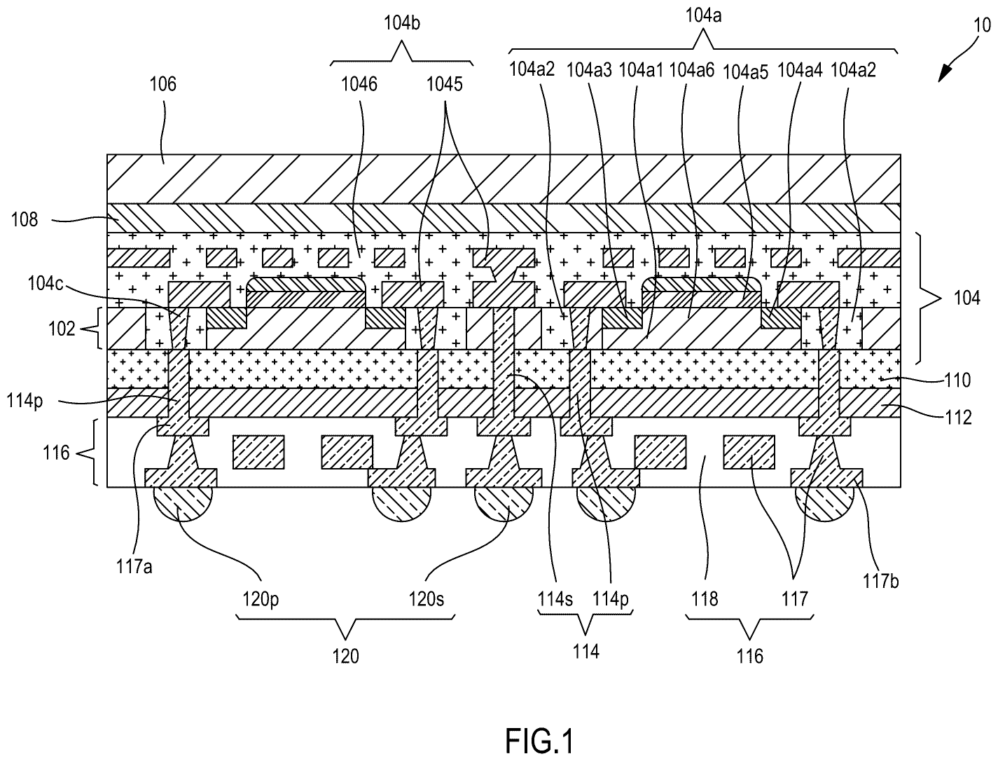

FIG. 1 shows a cross-sectional view of an example electronic device 10. In the example shown in FIG. 1, electronic device 10 can comprise device substrate 102, active region 104, support substrate 106, substrate dielectric 108, first passivation layer 110, second passivation layer 112, conductive vias 114, substrate 116, and external interconnects 120.

Active region 104 can comprise front end of line (FEOL) region 104a, back end of line (BEOL) region 104b, and buried power rails 104c. FEOL region 104a can comprise semiconductor body 104a1, isolation region 104a2, source module 104a3, drain module 104a4, gate module 104a5, and channel region 104a6. BEOL region 104b can comprise conductive structure 1045 and dielectric structure 1046. Conductive vias 114 can comprise power vias 114p and signal vias 114s. Substrate 116 can comprise conductive structure 117 and dielectric structure 118. Conductive structure 117 can comprise substrate inward terminals 117a and substrate outward terminals 117b. External interconnects 120 can comprise signal interconnects 120s and power interconnects 120p.

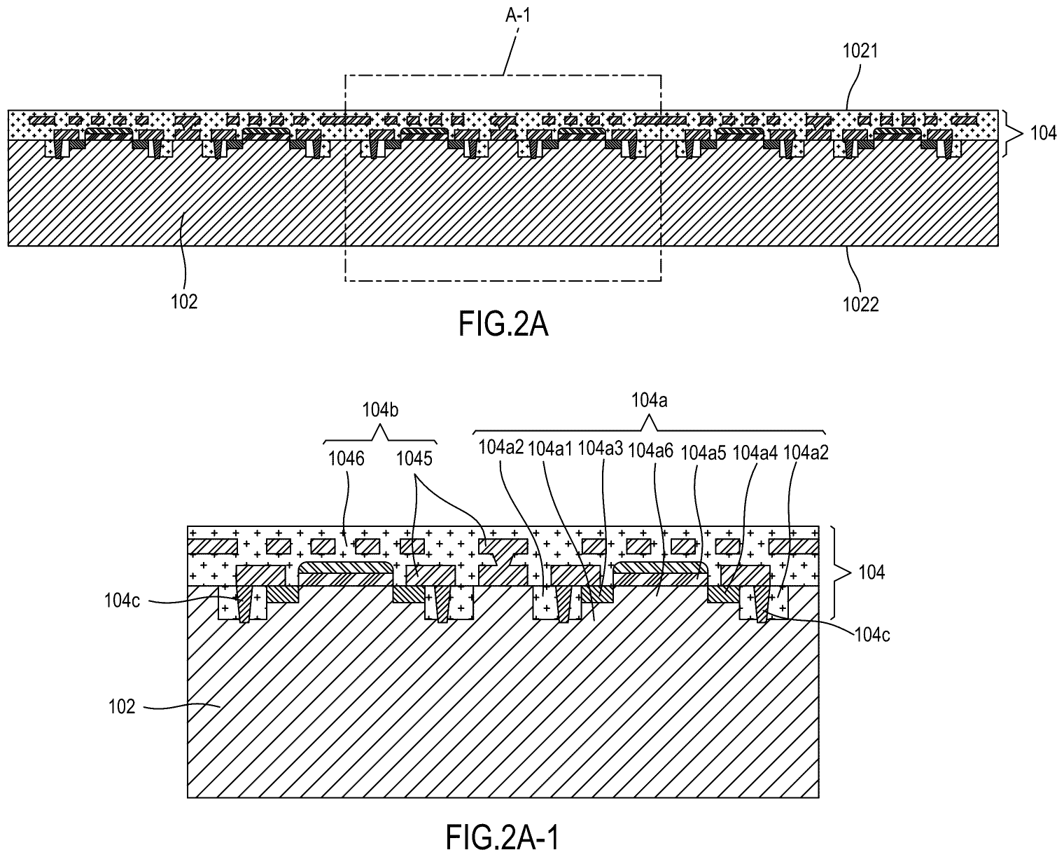

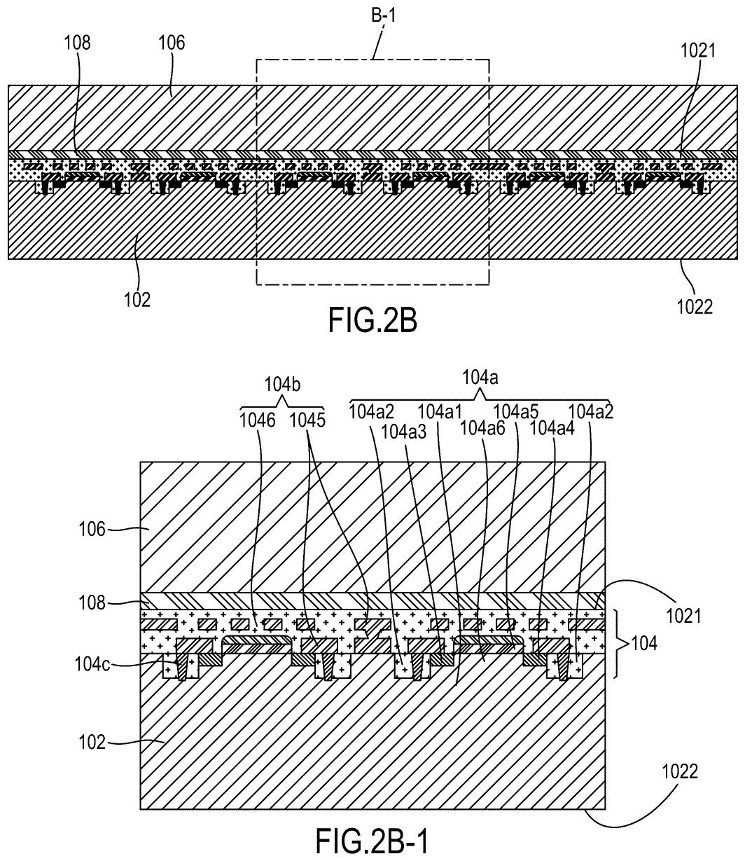

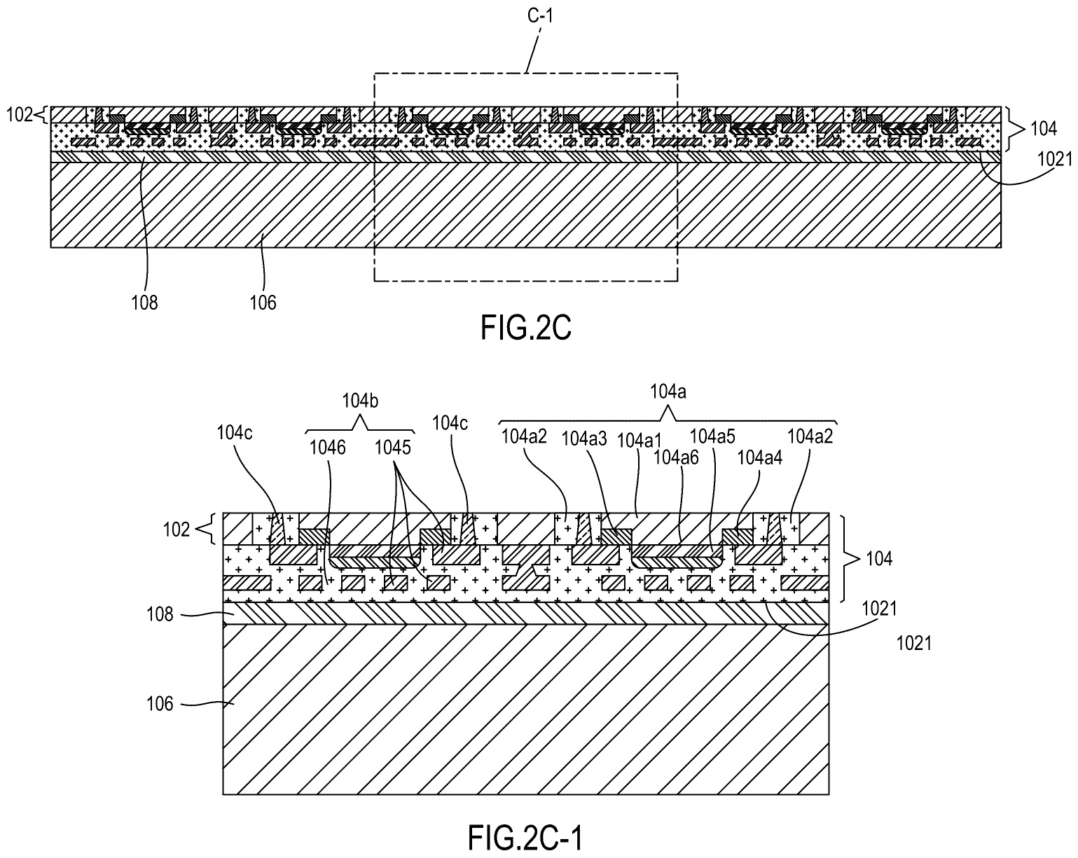

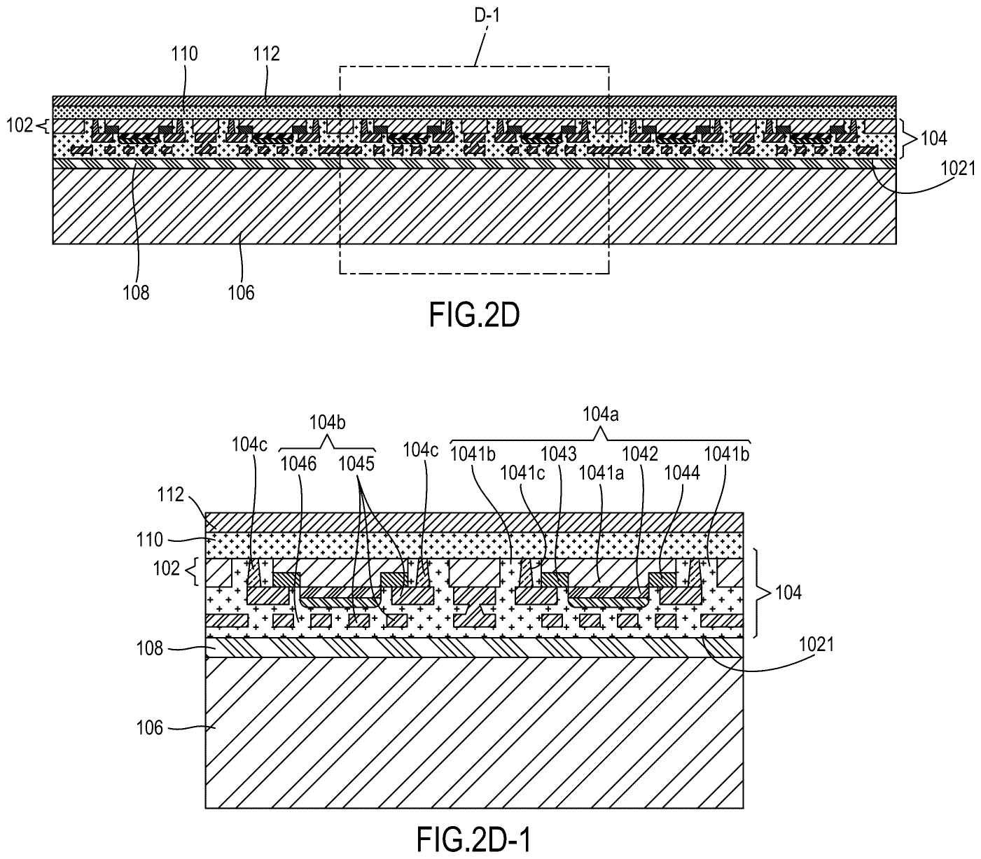

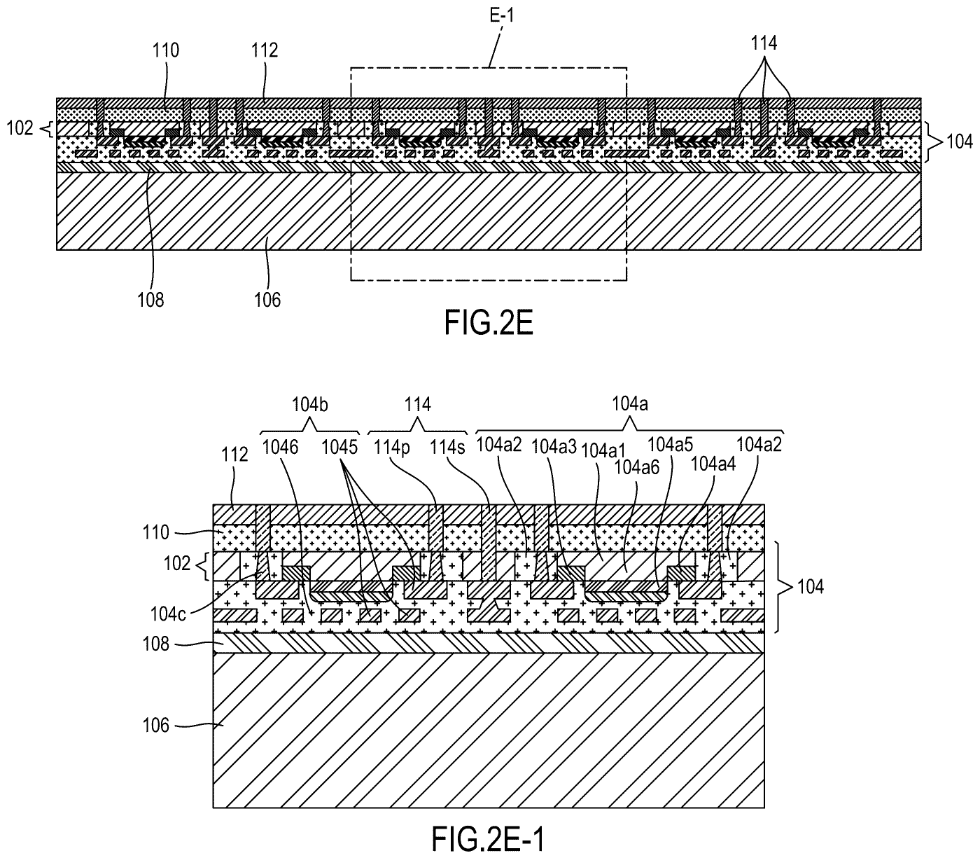

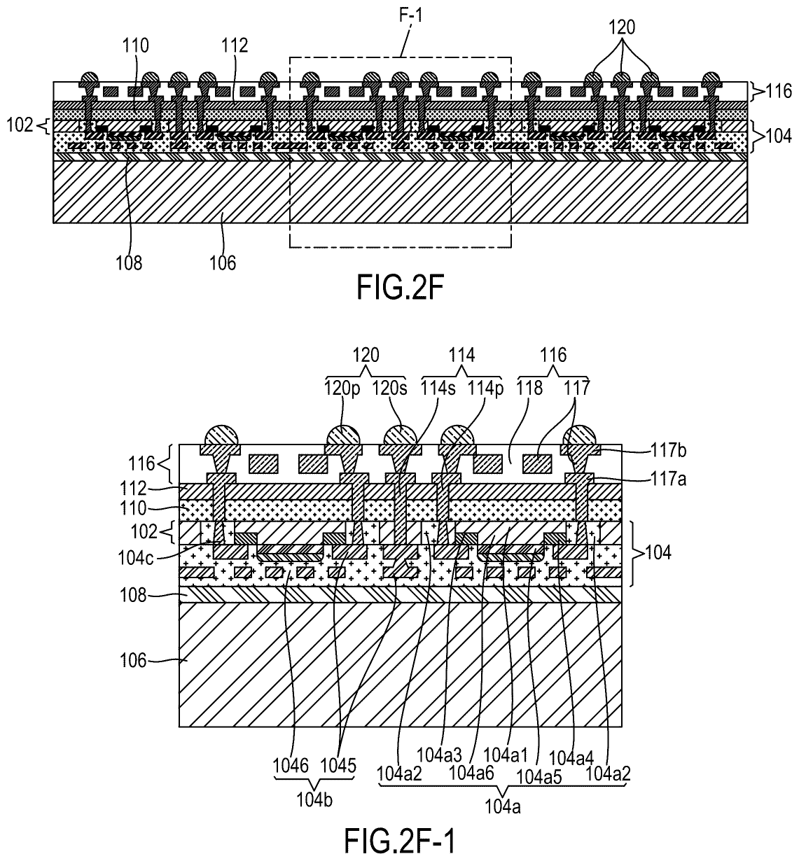

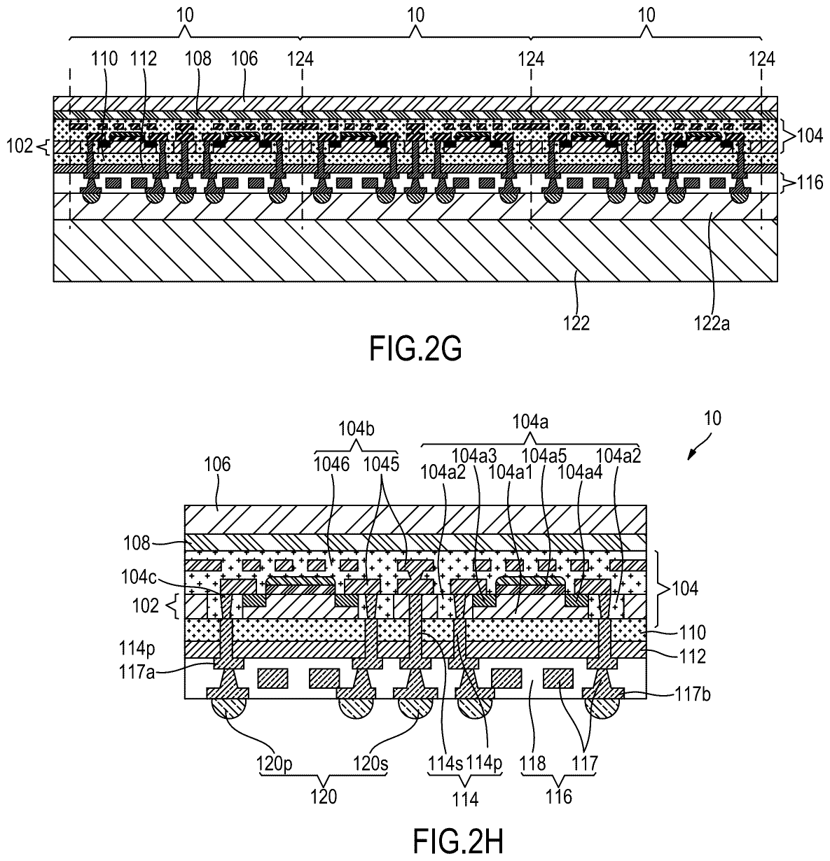

FIGS. 2A to 2H show an example method for manufacturing an electronic device, such as electronic device 10 of FIG. 1.

FIG. 2A shows a cross-sectional view of electronic device 10 at an early stage of manufacture. FIG. 2A-1 shows an enlarged view of electronic device 10 in region A-1 of FIG. 2A. In the example shown in FIGS. 2A and 2A-1, device substrate 102 can be provided. Device substrate 102 can comprise a semiconductor material or a wafer material, such as silicon (Si), germanium (Ge), gallium arsenide (GaAs), silicon carbide (SiC), or gallium nitride (GaN). Device substrate 102 can comprise or be referred to as a wafer, slice, substrate, single crystalline substrate, or crystalline substrate. In some examples, device substrate 102 can be provided through an ingot manufacturing process of making high-purity semiconductor solution and growing crystals at high temperature, an ingot slicing process of slicing an ingot to a uniform thickness by means of a diamond saw, a lapping and polishing process of processing a cut wafer as smooth as a mirror, and a fabrication (FAB) process of providing active region 104 on the surface of the wafer through a number of physical or chemical processes. The diameter of device substrate 102 can range from approximately 50 millimeters (mm) to approximately 300 mm. As used herein with numeric values, the term “approximately” can mean +/−5%, +/−10%, +/−15%, +/−20%, or +/−25%. In some examples, the width or diameter of device substrate 102 can be greater than 300 mm (e.g., the width or diameter of device substrate 102 can be 600 mm). It will be appreciated that the larger the diameter of device substrate 102, the more active regions 104 or electronic devices 10 can be included in device substrate 102.

In some examples, the thickness of device substrate 102 can range from approximately 400 micrometers (μm) to approximately 1000 μm. In some examples, the thickness of device substrate 102 can be reduced to approximately 350 μm to approximately 500 μm through a wafer backgrinding process. Device substrate 102 can comprise front side 1021 and back side 1022 opposite front side 1021. Device substrate 102 can comprise multiple active regions 104 including power devices, integrated circuits, or memories provided on front side 1021. In some examples, the multiple active regions 104 can be arranged in rows and columns on front side 1021 and can be isolated or otherwise separated from one another by scribe lines or saw streets. In accordance with various examples, each active region 104 can comprise a FEOL region 104a, BEOL region 104b, and embedded power rails 104c.

In some examples, FEOL region 104a can comprise semiconductor body 104a1, isolation region 104a2 (e.g., shallow trench isolation (STI)) provided around semiconductor body 104a1, source module 104a3 and drain module 104a4 provided in semiconductor body 104a1, and gate module 104a5 provided between source module 104a3 and drain module 104a4. In some examples, FEOL region 104a can comprise a sidewall spacer covering the lateral sides of gate module 104a5. The region between source module 104a3 and drain module 104a4 in semiconductor body 104a1 can define or be referred to as a channel region 104a6. In some examples, isolation region 104a2, source module 104a3, drain module 104a4, gate module 104a5, and channel region 104a6 can comprise or be referred to as a transistor (e.g., a field-effect transistor (FET), a metal-oxide semiconductor field-effect transistor (MOSFET), an insulated gate bipolar transistor (IGBT), a complementary metal-oxide-semiconductor (CMOS), or other type of transistor). In some examples, FEOL region 104a can include millions or billions of transistors, capacitors, or resistors.

In accordance with various examples, BEOL region 104b can be configured to interconnect the components (e.g., transistors, capacitors, or resistors) of FEOL region 104a. BEOL region 104b can comprise dielectric structure 1046 and conductive structure 1045. Dielectric structure 1046 can be provided over FEOL region 104a using physical vapor deposition (PVD), chemical vapor deposition (CVD), metal organic chemical vapor deposition (MOCVD), atomic layer deposition (ALD), low pressure chemical vapor deposition (LPCVD), plasma enhanced chemical vapor deposition (PECVD), printing, lamination, spin coating, spray coating, sintering, thermal oxidation, or any other suitable deposition process. Dielectric structure 1046 can comprise one or more layers of inorganic dielectric material, such as for example, SiO2, Si3N4, SiOxNy (where x and y are each a natural number), or SiCN.

In various examples, conductive structure 1045 can be provided within or interleaved with layers of dielectric structure 1046. Conductive structure 1045 can be formed using PVD, CVD, MOCVD, ALD, LPCVD, PECVD, electrolytic plating, electroless plating process, or any other suitable metal deposition process. In some examples, conductive structure 1045 can comprise one or more layers of Cu, Al, Au, Ag, Ni, Ti, TiW, Pd, Pt, or other suitable electrically conductive materials. In some examples, conductive structure 1045 can comprise horizontal traces and vertical vias and can be electrically coupled to source module 104a3, drain module 104a4, or gate module 104a5.

In accordance with various examples, power rails 104c can extend vertically through isolation region 104a2. Power rail 104c comprises a vertical conductive via and can be buried in isolation region 1041b. In some examples, power rail 104c can extend into the semiconductor material of device substrate 102. In some examples, power rail 104c can terminate at a surface device substrate 102. In some examples, power rails 104c can be electrically coupled to source module 104a3 and drain module 104a4 through conductive structure 1045. In some examples, components (e.g., traces and/or vias) of conductive structure 1045 electrically coupling power rails 104c to components of FOEL region 104a (e.g., to source module 104a3 and drain module 104a4) can be referred to as conductive structures for power, power components, conductive power components, power network, power delivery components, power structures, or similar terms or phrases. In one example, power rails 104c can support voltages of approximately 1 volt (V) to 250 V at approximately 50 ohms. Components (e.g., traces and/or vias) of conductive structure 1045 electrically coupling the components of FOEL region 104a to one another can be referred to as conductive structures for signals, signal structures, signal components, conductive signal components, signal network, signal transmission components, or similar terms or phrases. A signal network can support signals at lower voltages than a power network. In one example, the signal network can support voltages of approximately 0.001 V to 10 V.

FIG. 2B shows a cross-sectional view of electronic device 10 at a later stage of manufacture, and FIG. 2B-1 shows an enlarged view of electronic device 10 in region B-1 of FIG. 2B. In the example shown in FIGS. 2B and 2B-1, support substrate 106 is provided on front side 1021 of device substrate 102.

In accordance with various examples, support substrate 106 can be provided on active region 104 of device substrate 102. For example, support substrate 106 can be provided on BEOL region 104b. Support substrate 106 can comprise a semiconductor material, such as Si, Ge, GaAs, SiC, or GaN, a wafer material, or a glass material. Support substrate 106 can comprise or be referred to as a wafer, slice, single crystalline substrate, or crystalline substrate. In some examples, support substrate 106 can be provided through an ingot manufacturing process of making high-purity semiconductor solution and growing crystals at high heat, an ingot slicing process of slicing an ingot to a uniform thickness by means of a diamond saw, and a lapping and polishing process of processing a cut wafer as smooth as a mirror.

In some examples, support substrate 106 can comprise or be referred to as a non-pattern wafer (NPW), a recycled wafer, or a dummy wafer. The diameter (or width) and thickness of support substrate 106 can be similar to the diameter (or width) and thickness of device substrate 102. In some examples, the diameter or width of support substrate 106 can range from approximately 50 mm to approximately 300 mm. In some examples, the diameter or width of support substrate 106 can be greater than 300 mm (e.g., 600 mm). The thickness of support substrate 106 can range from approximately 400 μm to approximately 1000 μm in some examples.

In accordance with various examples, support substrate 106 comprises substrate dielectric 108. Substrate dielectric 108 can be provided on the lower side of support substrate 106 (e.g., on the side of support substrate 106 oriented toward device substrate 102). Substrate dielectric 108 can comprise or be referred to as an insulating material, an inorganic material, a dielectric structure, or an inorganic dielectric structure. The material of substrate dielectric 108 can be similar to or the same as the material of dielectric structure 1046 described above. In some examples, substrate dielectric 108 can comprise SiO2, Si3N4, SiOxNy, or SiCN. In some examples, substrate dielectric 108 can be provided using an oxidation process (e.g., by oxidizing support substrate 106) or a deposition process. For example, substrate dielectric 108 can be provided through PVD, CVD, MOCVD, ALD, LPCVD, or PECVD. The thickness of substrate dielectric 108 can range from approximately 1000 angstrom (Å) to approximately 1 μm.

In accordance with various examples, support substrate 106 can be coupled to device substrate 102. For examples, substrate dielectric 108 can be bonded to dielectric structure 1046. In some examples, the bonding process can be referred to as a wafer-to-wafer bonding process or a hybrid bonding process. The wafer-to-wafer bonding process can form a bond interface between adjacent surfaces or sides of the bonded wafers. In some examples, a planarization process can be performed before the wafer-to-wafer bonding process. For example, substrate dielectric 108 and/or dielectric structure 1046 can be planarized prior to bonding. In some examples, a planarization process can be performed in a manner similar to a chemical mechanical polishing (CMP) process. For example, the planarization process can be performed by providing a chemical slurry on a polishing pad and pressing and rotating substrate dielectric 108 or dielectric structure 1046 on the polishing pad. In some examples, the average surface roughness (Ra) of substrate dielectric 108 and dielectric structure 1046 after the planarization process can range from approximately 0.1 nm (nanometers) to approximately 5 nm. Planarizing the surfaces of substrate dielectric 108 and dielectric structure 1046 to within the foregoing surface roughness range tends to increase the interaction force between atoms and the strength of the bond interfaces. Planarizing the surfaces also tends to decrease the frequency and size of voids, and tends to prevent generation of voids between the bond interfaces.

In some examples, the bonding process can be performed by applying pressure in a state where substrate dielectric 108 and dielectric structure 1046 face each other and are in contact with each other. For example, the bonding process can include applying, by means of a pressure applying tool (e.g., a chuck), mechanical pressure to back side 1022 of device substrate 102 and to the opposing side of support substrate 106, opposite substrate dielectric 108. In some examples, the compressive force applied to substrate dielectric 108 and dielectric structure 1046 can range from approximately 10 Newton (N) to approximately 1000 N. In accordance with various examples, the force applied can be greater than or equal to approximately 100 N to increase the likelihood that substrate dielectric 108 and dielectric structure 1046 will sufficiently bond to each other. In some examples, the force applied can be less than approximately 1000 N to decrease or reduce the likelihood of damage to support substrate 106 or device substrate 102.

In some examples, an annealing process can be performed during or after the pressure applying process. The annealing temperature can range from approximately 250° C. to approximately 400° C. In some examples, if the annealing temperature is less than approximately 300° C., substrate dielectric 108 and dielectric structure 1046 may not sufficiently bond to one another. In some examples, if the annealing temperature is greater than approximately 400° C., already-formed active region 104 can be damaged or the characteristics of active region 104 can be changed. In some examples, the annealing temperature can be increased by using thermal rays or radio frequency (RF). In some examples, the radio frequency can be ultra-high frequency or millimeter waves or can comprise microwave waves in a frequency band ranging from approximately 2 GHz to approximately 5 GHz or from approximately 30 MHz to approximately 60 MHz.

In some examples, the time associated with an annealing process using thermal rays can range from approximately 1 hour to approximately 10 hours. In other examples, the annealing process using radio frequency (RF) can be completed in approximately 30 seconds to approximately 90 seconds (e.g., rapid annealing). In accordance with various examples, the rapid annealing can improve a bonding strength by inducing covalent bonds before the hydrophilicity of substrate dielectric 108 and dielectric structure 1046 can be reduced. In accordance with various examples, the annealing process using radio frequency (RF) tends to increase the temperature of only the region participating in bonding, (e.g., selective annealing of each region is possible). In this regard, the annealing process using radio frequency (RF) can be advantageous for controlling defects compared to annealing using a hot thermal wire. While substate dielectric 108 and dielectric structure 1046 are shown as distinct structures, it is contemplated and understood that after bonding, substrate dielectric 108 and dielectric structure 1046 may be indistinguishable from one another in some examples.

In accordance with various examples, the bond between dielectric structure 1046 and substrate dielectric 108 can initially start as a Van der Waals bond that progresses to a covalent bond through time or temperature. For example, bonding can be achieved between dielectric structure 1046 and substrate dielectric 108 through surface activation and a low temperature heat treatment process. For example, surface activation can be performed on dielectric structure 1046 and substrate dielectric 108 by generating hydrogen (H) on the surfaces of dielectric structure 1046 and substrate dielectric 108 through plasma treatment, oxygen (O) particles separated from water or air during plasma treatment can bind to hydrogen (H) on the surfaces of dielectric structure 1046 and substrate dielectric 108, and hydroxyl (OH) groups can be induced on the surfaces of dielectric structure 1046 and substrate dielectric 108. Surface activation allows for bonding between dielectric structure 1046 and substrate dielectric 108 at low temperatures. In some examples, dielectric structure 1046 and substrate dielectric 108 can be bonded to each other at temperatures ranging from approximately 25° C. to approximately 400° C. As used herein to describe temperatures, the term approximately can mean +/−5%, +/−10%, +/−15%, +/−20%, or +/−25%.

Substrate dielectric 108, together with dielectric structure 1046, tend to have excellent thermal conductivity across a thin inorganic insulator. Substrate dielectric 108 bonded with dielectric structure 1046 has a low hardness and tends to reduce the amount of wear imparted on the sawing tool used during singulation.

FIG. 2C shows a cross-sectional view of electronic device 10 at a later stage of manufacture, and FIG. 2C-1 shows an enlarged view of electronic device 10 in region C-1 of FIG. 2C. In the example shown in FIGS. 2C and 2C-1, a portion of device substrate 102 can be removed from back side 1022 (FIG. 2B).

In some examples, a chemical mechanical polishing (CMP) process can be performed on back side 1022. The CMP process can be applied to semiconductor body 104a1 of device substrate 102. The CMP process can be performed by pressing device substrate 102, with support substrate 106 coupled thereto, to a polishing pad while supplying chemical slurry to the rotating polishing pad. In some examples, the polishing pad and device substrate 102 can rub against each other while rotating in opposite directions. In some examples, the back side 1022 of device substrate 102 can be softened by the chemical slurry, and the softened back side 1022 can be removed by being ground by a mechanical force. In some examples, the speed of CMP polishing can be proportional to the product of pressure and speed (relative speed). In some examples, after the CMP process, a cleaning process for removing and drying impurities can be performed.

In some examples, the CMP process can include thinning device substrate 102 at least until exposing buried power rail 104c or isolation region 104a2. In this way, the upper side of buried power rail 104c or isolation region 104a2 can be exposed through the upper side of semiconductor body 104a1. In some examples after CMP, the upper side of buried power rail 104c or the upper side of isolation region 104a2 can be coplanar with the upper side of semiconductor body 104a1. In some examples, by providing a slurry with selectivity, the removal rate of the different structure or materials can be varied during the CMP process and the upper side of buried power rail 104c or the upper side isolation region 104a2 can be lower than or recessed from (i.e., not coplanar with) the upper side of semiconductor body 104a1. In some examples, the upper side of semiconductor body 104a1, as shown in the orientation of FIG. 2C-1, can be higher than or can protrude from the upper side of buried power rail 104c or the upper side of isolation region 104a2. In some examples, after CMP, the thickness of semiconductor body 104a1 or device substrate 102 can range from approximately 130 nm to approximately 250 nm.

FIG. 2D shows a cross-sectional view of electronic device 10 at a later stage of manufacture, and FIG. 2D-1 shows an enlarged view of electronic device 10 in region D-1 of FIG. 2D. In the example shown in FIGS. 2D and 2D-1, first passivation layer 110 and second passivation layer 112 are provided over device wafer 102.

In accordance with various examples, a passivation structure can be provided over the upper side of device substrate 102 (e.g., over the side opposite front side 1021). The passivation can comprise one or more passivation layers. A first passivation layer 110 can be provided over the upper side of device substrate 102. For example, first passivation layer 110 can be coupled to the upper sides of semiconductor body 104a1, buried power rails 104c, and isolation region 104a2. In some examples, first passivation layer 110 can contact exposed buried power rail 104c and isolation region 104a2. First passivation layer 110 can comprise or be referred to as an insulating material, an inorganic material, a dielectric structure, or an inorganic dielectric structure. In some examples, first passivation layer 110 can comprise SiO2, Si3N4, SiOxNy, or SiCN. First passivation layer 110 can be provided by oxidation or deposition. In some examples, first passivation layer 110 can be provided by PVD, CVD, MOCVD, ALD, LPCVD, or PECVD. The thickness of first passivation layer 110 can range from approximately 50 nm to approximately 150 nm. First passivation layer 110 together with semiconductor body 104a1 tend to provide excellent thermal conductivity. First passivation layer 110 together with semiconductor body 104a1 tend to have low hardness, which can reduce the wear imparted on the sawing tool used in singulation. In some examples, a CMP process can be performed on the upper side of first passivation layer 110, prior to providing second passivation layer 112.

In accordance with various examples, second passivation layer 112 can be provided on the upper side of first passivation layer 110. Second passivation layer 112 can comprise or be referred to as an insulating material, an inorganic material, a dielectric structure, or an inorganic dielectric structure. In some examples, second passivation layer 112 can comprise SiO2, Si3N4, SiOxNy, or SiCN. In some examples, second passivation layer 112 can be provided using techniques or structures similar to those described above for first passivation layer 110.

In some examples, the material of second passivation layer 112 can be different from the material of first passivation layer 110. For example, first passivation layer 110 can comprise SiO2, and second passivation layer 112 can comprise Si3N4, SiOxNy, or SiCN. In some examples in which first passivation layer 110 comprises Si3N4, SiOxNy, or SiCN, second passivation layer 112 can comprise SiO2. The thickness of second passivation layer 112 can range from approximately 50 nm to approximately 500 nm. Second passivation layer 112 together with first passivation layer 110 can provide excellent thermal conductivity. Second passivation layer 112 together with first passivation layer 110 can have a low hardness, which tends to reduce the wear imparted on a sawing tool used in singulation. In some examples, a CMP process can be performed on the upper side of second passivation layer 112.

FIG. 2E shows a cross-sectional view of electronic device 10 at a later stage of manufacture, and FIG. 2E-1 shows an enlarged view of electronic device 10 in region E-1 of FIG. 2E. In the example shown in FIGS. 2E and 2E-1, conductive vias 114 are provided through first passivation layer 110 and second passivation layer 112.

In accordance with various examples, conductive vias 114 can extend through and penetrate second passivation layer 112 and first passivation layer 110. In some examples, conductive vias 114 can comprise through-silicon vias (TSVs). One or more conductive vias 114 comprise signal via 114s and are coupled to conductive structure 1045 of BEOL 104b. In some examples, signal vias 114s extend through semiconductor body 104a1. In some examples, signal vias 114s can be electrically connected and contacting traces of conductive structure 1045.

In some examples, conductive vias 114 comprise one or more power vias 114p. Power vias 114p can penetrate second passivation layer 112 and first passivation layer 110. Power vias 114p can be coupled to the upper side of buried power rails 104c. Power vias 114p can be coupled to conductive structure 1045 to deliver or receive power via buried power rails 104c. For example, power vias 114p can be coupled to traces of conductive structure 1045 that are coupled to buried power rail 104c. In some examples, signal via 114s and power via 114p can be provided by a similar manufacturing processes. In some examples, signal via 114s can be longer than power via 114p and can include additional manufacturing processes compared to power via 114p.

In some examples, conductive vias 114 can be provided by forming a hole or opening, providing a barrier in the hole, providing a seed layer over the barrier, and providing a conductor over the seed layer. In some examples, holes can be provided by sequentially penetrating second passivation layer 112 and first passivation layer 110 and in some areas by sequentially penetrating second passivation layer 112, first passivation layer 110, and semiconductor body 104a1. In some examples, the holes can be provided at locations corresponding to conductive signals structures of conductive structure 1045 and at locations corresponding to conductive power structures of conductive structure 1045. Holes can be provided by laser drilling, chemical etching, deep reactive ion etching (DRIE), or any other suitable formation technique. In some examples, the depths of the holes can vary, and additional etching can be performed to provide deeper holes. For example, the diameter of the holes can range from approximately 15 nm to approximately 300 nm, from approximately 20 nm to approximately 275 nm, from approximately 25 nm to approximately 250 nm, or from approximately 30 nm to approximately 200 nm. Example measurements of distance given in the present disclosure are meant for example purposes only and are not limiting.

In various examples, the depths of the holes can range from approximately 100 nm to approximately 650 nm and from approximately 230 nm to approximately 900 nm. For example, the holes extending to buried power rails 104c can have a depth between approximately 100 nm and approximately 650 nm, which can correspond to the combined thickness of first passivation layer 110 and second passivation layer 112. The holes extending to conductive structure 1045 of BEOL region 104b can have a depth between approximately 230 nm to approximately 900 nm, which can correspond to the combined thickness of first passivation layer 110, second passivation layer 112, and semiconductor body 104a1. In response to the hole providing process, the upper side of the conductive signal structures can be exposed through semiconductor body 104a1, and the upper side of buried power rail 104c can be exposed through first and second passivation layers 110, 112. In some examples, isolation region 104a2 can serve as an etch stop. For example, the lower sides of the holes can be formed, provided, or defined by the upper side of isolation region 104a2.

In some examples, a dielectric layer (or an insulating layer) can be provided on the inner walls of the holes. When the inner walls of the holes contain silicon, the dielectric layer can comprise an inorganic film such as SiO2 or Si3N4. When the inner walls of the holes contain glass or ceramic, the dielectric layer can comprise an organic film such as polyimide (PI), benzocyclobutene (BCB), or polybenzoxazole (PBO). The dielectric layer can be provided by PVD, CVD, MOCVD, ALD, LPCVD, or PECVD. In some examples, regions of the dielectric layer provided at the bottoms of the holes can be removed such that the dielectric layer remains on the side walls of the holes. Removal of regions of the dielectric layer can be done by laser or chemical etching. The thickness of the dielectric layer can range from approximately 1 nm to approximately 30 nm, from approximately 2 nm to approximately 25 nm, from approximately 3 nm to approximately 20 nm, from approximately 4 nm to approximately 15 nm, or any other suitable thickness. Different materials used in the dielectric layer can be provided in different thicknesses suitable to the characteristics of the selected materials. The dielectric layer can improve electrical reliability by inhibiting or reducing the electrical shorts of conductive vias 114.

In some examples of the barrier-providing process, an adhesion-and-diffusion preventing layer can be provided on the inner walls (e.g., side walls) of the dielectric layer. The adhesion-and-diffusion preventing layer can comprise Ta, TaN, TiN, or Ru. The adhesion-and-diffusion preventing layer can be provided by sputtering, PVD, CVD, MOCVD, ALD, LPCVD, or PECVD. In some examples, the adhesion-and-diffusion preventing layer can be provided on the bottom side defining the holes. For example, the adhesion-and-diffusion preventing layer can be provided on the region of buried power rail 104c that defines the bottoms of the holes, or on the region of conductive structure 1045 that defines the bottoms of the holes. The thickness of the adhesion-and-diffusion preventing layer can range from approximately 4 nm to approximately 10 nm. The adhesion-and-diffusion preventing layer can improve adhesion characteristics of a seed layer or a conductor coupled to the inner walls defining the holes in a subsequent stage. The adhesion-and-diffusion preventing layer tends to prevent metal ions from diffusing into the inner walls of the holes.

In some examples of the seed layer providing process, a seed layer can be provided on the inner walls of the adhesion-and-diffusion preventing layer. In some examples, the seed layer can comprise Ti, TiW, Cu, or Au. The seed layer can be provided by sputtering, PVD, CVD, MOCVD, ALD, LPCVD, or PECVD. In some examples, the seed layer can be deposited on the structures of conductive structure 1045 corresponding to the bottoms of the holes (e.g., exposed signal traces). In some examples, the adhesion-and-diffusion preventing layer can be interposed between the exposed conductive signal structures of conductive structure 1045 and the seed layer. In some examples, the seed layer can be deposited on or over areas of buried power rail 104c corresponding to the bottoms of the holes. In some examples, the adhesion-and-diffusion preventing layer can be interposed between the buried power rail 104c and the seed layer. The thickness of the seed layer can range from approximately 1 nm to approximately 10 nm, or can be any suitable thickness for the seed layer to fit on the inner walls defining a hole and allow space for the conductor inside the hole. The seed layer can provide a path for the flow of current when a conductor is electroplated onto the inner walls of the holes.

In some examples of the conductor providing process, a conductor can be provided on the seed layer. In some examples, the conductor can fill the holes (e.g., the hole can contain or include the dielectric layer, adhesion-and-diffusion preventing layer, seed layer, and conductor). The conductor can comprise Cu, Al, Ni, Au, Ag, Pt, or any other suitable conductive material. In some examples, the holes can be filled with the conductor by an electrolytic plating method. In general, when a metal is plated at a low current density, it tends to be easier to form a uniform plating layer, enabling defect-free filling but having a slow plating speed. Slow plating speed tends to increase the filling time. Conversely, when high-current-density plating is employed, the plating speed tends to increase so that the filling time can be shortened, but the entrances of the holes can become clogged, which can cause defects. Accordingly, the current density related to plating can be adjusted in consideration of various process variables, such as hole diameters or hole depths. The diameter of the conductor can range from approximately 10 nm to approximately 260 nm, from approximately 20 nm to approximately 230 nm, from approximately 30 nm to approximately 200 nm, or any other suitable diameter to fill open space between the inner walls of the hole or between adjacent sides of the seed layer on the inner walls. The length of the conductor in a vertical direction can range from approximately 100 nm to approximately 650 nm and from approximately 230 nm to approximately 900 nm, depending on the depth of the hole. The conductor can be electrically connected to the power structure of conductive structure 1045 through buried power rail 104c or to signal structures of conductive structure 1045 for signals.

In some examples, after providing conductive vias 114, a planarization process or a CMP process can be performed. In some examples, after the planarization process, the upper sides of conductive vias 114 can be coplanar with the upper side of second passivation layer 112.

FIG. 2F shows a cross-sectional view of electronic device 10 at a later stage of manufacture, and FIG. 2F-1 shows an enlarged view of electronic device 10 in region F-1 of FIG. 2F. In the example shown in FIGS. 2F and 2F-1, substrate 116 can be provided over second passivation layer 112.

In accordance with various embodiments, substrate 116 can comprise dielectric structure 118 and conductive structure 117. Dielectric structure 118 can comprise one or more dielectric layers made of dielectric material (e.g., polymer, polyimide (PI), benzocyclobutene (BCB), polybenzoxazole (PBO), bismaleimide triazine (BT), resin, Ajinomoto Buildup Film (ABF), Si3N4, SiO2, SiON, etc.) and interleaved between layers of conductive structure 117. Dielectric structure 118 can be provided by PVD, CVD, MOCVD, ALD, LPCVD, PECVD, or any other suitable deposition process. Conductive structure 117 can comprise one or more conductive layers defining signal distribution elements (e.g., traces, vias, pads, conductive paths, UBMs, etc.) interleaved between layers of dielectric structure 118. Conductive structure 117 can comprise Al, Cu, Au, Ag, Ni, Pd, or other suitable conductive material. Conductive structure 117 can be formed using PVD, CVD, MOCVD, ALD, LPCVD, PECVD, electrolytic plating, electroless plating process, or any other suitable metal deposition process. Conductive structure 117 can distribute power and electrical signals in a vertical direction and a lateral direction through substrate 116. In some examples, conductive structure 117 can comprise a power network configured to deliver and distribute power within electronic device 10, and conductive structure 1045 can comprise a signal network configured to deliver and distribute signals within electronic device 10.

Conductive structure 117 can comprise inward terminals 117a and outward terminals 117b. Inward terminals 117a can be coupled to conductive vias 114. For example, inward terminals 117a can be coupled to or contact power vias 114p and signal vias 114s. In some examples, inward terminals 117a can comprise or be referred to as pads, lands, UBMs, or studs. In some examples, the lower sides of inward terminals 117a can be coplanar with the lower side of dielectric structure 118, as shown in the orientation of FIG. 2F-1. Outward terminals 117b can be provided at the upper side of substrate 116 (i.e., the side opposite inward terminals 117a). Conductive structures (e.g., traces and vias) of conductive structure 117 can electrically couple inward terminals 117a and outward terminals 117b. Outward terminals 117b can comprise or be referred to as pads, two-step pads, lands, or UBM. In some examples, the upper sides of outward terminals 117b can be coplanar with the upper side of dielectric structure 118, as shown in the example of FIG. 2F-1. In some examples, outward terminals 117b can protrude from the upper side of dielectric structure 118, as shown in the orientation of FIG. 2F-1. In some examples, individual layers of dielectric structure 118 and conductive structure 117 can range from approximately 6 μm to approximately 30 μm in thickness. In some examples, the overall thickness of substrate 116 can range from approximately 10 μm to approximately 40 μm. Substrate 116, comprising dielectric structure 118 and conductive structure 117, can support active region 104, support substrate 106 and substrate dielectric 108. Substrate 116 can couple active region 104 to external interconnects 120.

In various examples, substrate 116 can comprise a redistribution layer (“RDL”) substrate. RDL substrates can comprise one or more conductive redistribution layers and one or more dielectric layers and (a) can be formed layer by layer over an electronic device to where the RDL substrate is to be coupled, or (b) can be formed layer by layer over a carrier and can be entirely removed or at least partially removed after the electronic device and the RDL substrate are coupled together. RDL substrates can be manufactured layer by layer as a wafer-level substrate on a round wafer in a wafer-level process, and/or as a panel-level substrate on a rectangular or square panel carrier in a panel-level process. RDL substrates can be formed in an additive buildup process and can include one or more dielectric layers alternatingly stacked with one or more conductive layers and define respective conductive redistribution patterns or traces configured to collectively (a) fan-out electrical traces outside the footprint of the electronic device, and/or (b) fan-in electrical traces within the footprint of the electronic device. The conductive patterns can be formed using a plating process such as, for example, an electroplating process or an electroless plating process. The conductive patterns can comprise a conductive material such as, for example, copper or other plateable metal. The locations of the conductive patterns can be made using a photo-patterning process such as, for example, a photolithography process and a photoresist material to form a photolithographic mask. The dielectric layers of the RDL substrate can be patterned with a photo-patterning process, and can include a photolithographic mask through where light is exposed to photo-pattern desired features, such as vias in the dielectric layers. The dielectric layers can be made from photo-definable organic dielectric materials such as, for example, polyimide (PI), benzocyclobutene (BCB), or polybenzoxazole (PBO). Such dielectric materials can be spun-on or otherwise coated in liquid form, rather than attached as a pre-formed film. To permit proper formation of desired photo-defined features, such photo-definable dielectric materials can omit structural reinforcers or can be filler-free, without strands, weaves, or other particles, and could interfere with the light from the photo-patterning process. In some examples, such filler-free characteristics of filler-free dielectric materials can permit a reduction of the thickness of the resulting dielectric layer. Although the photo-definable dielectric materials described above can be organic materials, in some examples the dielectric materials of the RDL substrates can comprise one or more inorganic dielectric layers. Some examples of inorganic dielectric layers can comprise silicon nitride (Si3N4), silicon oxide (SiO2), and/or SiON. The inorganic dielectric layers can be formed by growing the inorganic dielectric layers using an oxidation or nitridization process instead of using photo-defined organic dielectric materials. Such inorganic dielectric layers can be filler-free, without strands, weaves, or other dissimilar inorganic particles. In some examples, the RDL substrates can omit a permanent core structure or carrier such as, for example, a dielectric material comprising bismaleimide triazine (BT) or FR4, and these types of RDL substrates can comprise or be referred to as a coreless substrate.

In some examples, substrate 116 can be a pre-formed substrate. Pre-formed substrates can be manufactured prior to attachment to an electronic device and can comprise dielectric layers between respective conductive layers. The conductive layers can comprise copper and can be formed using an electroplating process. The dielectric layers can be relatively thicker non-photo-definable layers, can be attached as a pre-formed film rather than as a liquid, and can include a resin with fillers such as strands, weaves, and/or other inorganic particles for rigidity and/or structural support. Since the dielectric layers are non-photo-definable, features such as vias or openings can be formed by using a drill or laser. In some examples, the dielectric layers can comprise a prepreg material or an Ajinomoto buildup film (ABF). The pre-formed substrate can include a permanent core structure or carrier such as, for example, a dielectric material comprising bismaleimide triazine (BT) or FR4, and dielectric and conductive layers can be formed on the permanent core structure. In other examples, the pre-formed substrate can be a coreless substrate and omit the permanent core structure, and the dielectric and conductive layers can be formed on a sacrificial carrier, which can be removed after formation of the dielectric and conductive layers and before attachment to the electronic device. The pre-formed substrate can be referred to as a printed circuit board (PCB) or a laminate substrate. Such pre-formed substrate can be formed through a semi-additive or modified-semi-additive process.

In some examples, external interconnects 120 can be provided on substrate 116. External interconnects 120 can comprise signal interconnects 120s coupled to signal vias 114s via conductive structure 117. External interconnects 120 can comprise power interconnects 120p connected to power vias 114p via conductive structure 117. External interconnects 120 can be provided on outward terminals 117b by a plating or deposition process. External interconnects 120 can comprise or be referred to as conductive pillars, conductive balls, conductive bumps, or solder balls. In some examples, a conductive pillar can be provided on outward terminals 117b by plating or depositing Cu, Al, Au, Ag, Ni, or SnAg on outward terminals 117b. In some examples, flux or flowable material can be provided on outward terminals 117b, conductive balls are dropped on the flux, and the conductive balls can then be provided on outward terminals 117b through a reflow process or a laser-assisted bonding process. In some examples, the conductive balls can comprise Sn, Ag, Pb, Cu, Sn—Pb, Sn37-Pb, Sn95-Pb, Sn—Pb—Ag, Sn—Cu, Sn—Ag, Sn—Au, Sn—Bi, or Sn—Ag—Cu. In some examples, the thicknesses or widths of external interconnects 120 can range from approximately 0.01 mm to approximately 0.5 mm. External interconnects 120 can serve to couple electronic device 10 to an external device.

FIG. 2G show cross-sectional views of electronic device 10 at later stages of manufacture. In the example shown in FIG. 2G, grinding and singulation can be performed. FIG. 2H shows electronic device 10 after singulation.

In accordance with various examples, after providing external interconnects 120, electronic device 10 can be bonded to carrier 122 through temporary bond layer 122a. In some examples, external interconnects 120 and substrate 116 can be bonded to carrier 122 through temporary bond layer 122a. Carrier 122 can comprise or be referred to as a support, a tape, a plate, a panel, or a wafer. Temporary bond layer 122a can comprise or be referred to as a temporary bonding film, a temporary bonding tape, a temporary adhesive coating, a heat release tape (or film), or an optical release tape (or film). In some examples, external interconnects 120 can be located in temporary bonding layer 122a and can be spaced apart from the surface of the carrier 122.

The upper side of support substrate 106 (i.e., the side opposite substrate 16 and carrier 122) can be thinned to a predetermined thickness by a grinding process. In some examples, the grinding can be performed by quickly grinding the upper side of support substrate 106 to a reference thickness by means of a grinding pad having relatively large abrasive particles, and then finely grinding the upper side of support substrate 106 by means of a grinding pad having relatively small abrasive particles. In some examples, after grinding, the remaining thickness of support substrate 106 can range from approximately 250 μm to approximately 400 μm. Through the grinding process, the thickness of support substrate 106 and, thus the overall thickness of electronic device 10, can be reduced.

After the grinding process, electronic device 10 can be separated from carrier 122. In some examples, separation can be performed by chemical, optical, or mechanical methods. In some examples, the bonding strength of temporary bond layer 122a can be reduced by a chemical solution, and electronic device 10 can be separated from the carrier 122. In some examples, the bonding strength of temporary bond layer 122a can be reduced by light (e.g., visible light, ultraviolet light, or infrared light), and electronic device 10 can be separated from carrier 122. In some examples, electronic device 10 can be forcibly separated from carrier 122 by a mechanical force. In some examples, the separation process can be performed before or after singulation.

After the grinding process or the separation process, a singulation process can be performed. During singulation, device substrate 102, which includes multiple electronic devices 10, can be separated into individual, discrete electronic devices 10 by sawing along saw street 124. In some examples, a diamond blade wheel or a laser beam can be used for singulation. The singulation process can include cutting through support substrate 106, substrate dielectric 108, active region 104, first passivation layer 110, second passivation layer 112, and substrate 116 using a sawing tool. After the singulation process, the lateral sides of support substrate 106, substrate dielectric 108, active region 104, first passivation layer 110, second passivation layer 112, and substrate 116 can be coplanar with one another. In some examples, since the hardnesses of support substrate 106, substrate dielectric 108, active region 104, first passivation layer 110, second passivation layer 112, and substrate 116 can be less than the hardness of an encapsulant containing Al2O3, the wear imparted on the sawing tool can be reduced as compared to device that are singulated by sawing through the encapsulant containing Al2O3.

Techniques and structures described herein can provide overall low-cost electronic device 10 by using a wafer-to-wafer bonding process. The wafer-to-wafer bonding process can replace the previously known and costly silicon-on-insulation (SOI) process. Since the heat conductivities of support substrate 106, substrate dielectric 108, first passivation layer 110, and second passivation layer 112 are relatively high, heat from active region 104 can be quickly released or dissipated. The performance of electronic device 10 may thus resist deterioration in a high-temperature environment. By providing a power network and a signal network mainly on opposite sides of device substrate 102 (e.g. on opposite sides of FEOL region 104a), high-performance electronic device 10 can be provided. The sawing tool used in singulation can also experience reduced wear, which in turn can reduce the overall manufacturing cost for electronic device 10.

The present disclosure includes reference to certain examples, however, it will be understood by those skilled in the art that various changes may be made and equivalents may be substituted without departing from the scope of the disclosure. In addition, modifications may be made to the disclosed examples without departing from the scope of the present disclosure. Therefore, it is intended that the present disclosure not be limited to the examples disclosed, but that the disclosure will include all examples falling within the scope of the appended claims.

What is claimed is:

1. A method of manufacturing an electronic device, comprising:
providing a device wafer including an active region comprising a front-end-of-line (FEOL) region opposite a back-end-of-line (BEOL) region, the FEOL region including buried power rails, the BEOL region including a dielectric structure having a side exposed from the BEOL region;
providing a support substrate having a substrate dielectric coupled to the dielectric structure, wherein a bond interface is disposed between the substrate dielectric and the dielectric structure;
providing a passivation structure over the FEOL region;
providing conductive vias through the passivation structure, the conductive vias comprising a conductor coupled to the buried power rails; and
providing a substrate coupled to the passivation structure, the substrate comprising a power network electrically coupled to the conductive vias.

2. The method of claim 1, wherein providing the passivation structure further comprises:
providing a silicon-oxide (SiO2) layer over the FEOL region; and
providing a silicon-nitride layer (SiN) layer over the SiO2 layer.

3. The method of claim 2, wherein providing the conductive vias further comprises:
forming an opening defined through the SiO2 layer and through the SiN layer; and
providing the conductor in the opening.

4. The method of claim 1, wherein the BEOL region comprises a signal network configured to distribute signals within the electronic device.

5. The method of claim 1, further comprising applying an annealing temperature and a compressive force to the support substrate and the device wafer to form the bond interface.

6. The method of claim 5, wherein the annealing temperature comprises approximately 250 degrees Celsius to approximately 400 degrees Celsius.

7. The method of claim 1, wherein providing a passivation structure over the FEOL region further comprises:
removing a semiconductor material from a back side of the device wafer to expose a side of the FEOL region; and
providing the passivation structure over the exposed side of the FEOL region.

8. An electronic device, comprising:
a device wafer including an active region comprising a front-end-of-line (FEOL) region opposite a back-end-of-line (BEOL) region, the FEOL region including buried power rails, the BEOL region including a dielectric structure having a side exposed from the BEOL region;
a support substrate having a substrate dielectric coupled to the dielectric structure, wherein a bond interface is disposed between the substrate dielectric and the dielectric structure;
a passivation structure disposed over the FEOL region;
conductive vias extending through the passivation structure, the conductive vias comprising a conductor coupled to the buried power rails; and
a substrate coupled to the passivation structure, the substrate comprising a power network electrically coupled to the conductive vias.

9. The electronic device of claim 8, wherein the passivation structure comprises:
a silicon-oxide (SiO2) layer coupled to the FEOL region; and
a silicon-nitride layer (SiN) layer coupled to the SiO2 layer.

10. The electronic device of claim 9, wherein the conductor of the conductive vias extends through the SiO2 layer and through the SiN layer.

11. The electronic device of claim 8, wherein the passivation structure comprises a single passivation layer.

12. The electronic device of claim 8, wherein the bond interface is formed by applying an annealing temperature and a compressive force to the support substrate and the device wafer.

13. The electronic device of claim 8, further comprising external interconnects coupled to an exposed side of the substrate, wherein the external interconnects are electronically coupled to the power network.

14. The electronic device of claim 8, wherein a buried power rail from the buried power rails is enclosed by an isolation region of the FEOL region, a conductive via from the conductive vias, and the BEOL region.

15. The electronic device of claim 8, wherein the BEOL region comprises a signal network configured to distribute signals within the electronic device.

16. An electronic device, comprising:
a device wafer including buried power rails in an active region, the active region including a dielectric structure on a first side;
a support substrate coupled to the dielectric structure with a bond interface disposed between the support substrate and the dielectric structure;
a passivation structure coupled to a second side of the active region opposite the first side;
conductive vias extending through the passivation structure, the conductive vias coupled to the buried power rails; and
a substrate coupled to the passivation structure, the substrate comprising a power network electrically coupled to the conductive vias.

17. The electronic device of claim 16, wherein the passivation structure comprises:
a silicon-oxide (SiO2) layer coupled to the active region; and
a silicon-nitride layer (SiN) layer coupled to the SiO2 layer.

18. The electronic device of claim 16, wherein the bond interface is formed by a hybrid bonding process comprising:
applying a compressive force to the support substrate and the device wafer; and
applying an annealing temperature to the support substrate and the device wafer.

19. The electronic device of claim 16, wherein a buried power rail from the buried power rails is enclosed by an isolation region of the active region, a conductive via from the conductive vias, and a conductive structure of the active region.

20. The electronic device of claim 16, wherein a back-end-of-line region of the active region comprises a conductive structure, the conductive structure comprising a signal network configured to distribute signals within the electronic device.
